(19) United States
(12) Patent Application Publication
(10) Pub. No.: US 2014/0287587 A1
(43) Pub. Date: Sep. 25, 2014

(54) Method for Forming Fine Patterns of Semiconductor Device Using Directed Self-Assembly Process

(71) Applicant: DONGJIN SEMICHEM CO., LTD, Incheon (KR)

(72) Inventors: Jung-Youl Lee, Anyang-si, (KR); Eu-Jean Jang, Hwaseong-si (KR); Jae-Woo Lee, Bucheon-si (KR); Jae-Hyun Kim, Seoul (KR)

(73) Assignee: DONGJIN SEMICHEM CO., LTD, Incheon (KR)

(21) Appl. No.: 14/346,080

(22) PCT Filed: Sep. 27, 2012
(86) PCT No.: PCT/KR2012/007837

§ 371 Date: Mar. 20, 2014

(30) Foreign Application Priority Data
Sep. 29, 2011 (KR) 10-2011-0098838

(51) Int. Cl. H01L 21/308

(52) U.S. Cl. CPC H01L 21/3086
USPC 438/694

(57) ABSTRACT

Provided herein is a method for forming fine patterns of semiconductor devices capable of forming patterns with 20 nm-level line width without bulk-exposure and hardening of guide patterns. Method steps include (a) forming a photoresist layer over a wafer on which an organic anti-reflection coating layer is formed; (b) exposing and developing the photoresist layer to form guide patterns; (c) forming a neutral layer over the wafer; (d) developing the guide patterns to remove them and form neutral layer patterns having an opening part; (e) coating block copolymer of directed self assembly material on the substrate and heating the substrate over a glass transition temperature (Tg) to form directed self-assembly patterns; and (f) selectively etching a part having relatively small etching resistivity (or high etching rate) among the directed self-assembly patterns by using O₂ plasma to form fine patterns.

### FIELD OF THE INVENTION

This invention relates to a method for forming fine patterns of semiconductor devices, and more particularly to a method for forming fine patterns of semiconductor devices capable of forming patterns with 20 nm-level line width by using a directed self-assembly process (lithography) without bulk-exposure and hardening of guide patterns.

### BACKGROUNDS OF THE INVENTION

A down-scale and higher integration degree of the semiconductor devices has required a technique for realizing fine patterns of the semiconductor devices. Among methods for forming fine patterns of the semiconductor device, it is the best effective method to use the fine photoresist patterns, which is obtained through development of the exposing tools and introduction of a new progressive process technology. However, the development of the exposing tools results in much investment cost and reduces the utilization of the conventionally existing tools. Thus, a study on new process technology is more actively have been conducted.

A directed self-assembly (DSA) lithography using an automatic orientation of a block copolymer (BCP), among the new processes, is expected to be capable of forming fine patterns having a line width of 20 nm or less, which is known as the limit of a conventional optical pattern formation technology.

A method for forming fine patterns of semiconductor devices using the DSA lithography can be modified according to a photoresist composition for forming guide patterns, for example, photoresist composition using ArF, KrF, I-line EUV, E-beam as the light source. In one manner for forming fine patterns of semiconductor devices, guide patterns are formed on a neutral layer, a BCP coating layer is formed over a space between guide patterns, and the BCP coating layer is subject to a heating treatment at a temperature over a glass transition temperature (Tg) and then is rearranged, so a self-assembly pattern with an ordered orientation can be obtained. Alternatively, the guide patterns are formed and hardened, the neutral layer is formed on the guide patterns, the guide patterns are removed by developing, a BCP coating layer is formed on a substrate on which the guide patterns are removed and a part of the neutral layer remains, and the BCP coating layer is subject to a heating treatment at a temperature over a glass transition temperature (Tg) and then is rearranged, so a self-assembly pattern with an ordered orientation can be obtained. Specifically, when the ArF photoresist composition is used for forming the guide patterns in the latter method for forming fine patterns of semiconductor devices, the semiconductor patterns having 20 nm-level line width can be efficiently formed.

FIG. 1 is a drawing of cross-sectional views of semiconductor substrate for illustrating the latter method for forming fine patterns of semiconductor devices by using the DSA lithography. As shown in FIG. 1, a conventional method for forming fine patterns of semiconductor devices using the DSA lithography comprises the steps of (A) coating a photoresist composition over a substrate (10) on which an organic anti-reflection coating layer (12) is formed to form a photoresist layer (14), (B) exposing and developing the photoresist layer (14) to form guide patterns (photoresist patterns, 16), (C) bulk-exposing the guide patterns (16) without a photo mask and then heating at 200 to 220° C. to form hardened patterns (16a), (D) coating a neutral layer (18) over the hardened patterns (16a), (E) removing the hardened patterns (16a) by using TMAH developing solution to form a neutral layer patterns (18a) having an opening part which was made by the removal of the guide patterns, (F) coating BCP of DSA material on the substrate (10) on which the neutral layer patterns (18a) are formed, heating the substrate (10) at a temperature over a glass transition temperature (Tg) (for example 200 to 300° C.) to form directed self-assembly patterns (20a, 20b), and (G) selectively etching a part (20b) having relatively small etching resistivity (or high etching rate) among the directed self-assembly patterns (20a, 20b) by using O₂ plasma to form fine patterns. As described above, the method for forming fine patterns must contain a step of bulk-exposing the guide patterns (16) of photoresist composition and heating to hardened (C step) in order to prevent the photoresist patterns (16) which is developed by positive-tone developing solution, from dissolving in the organic solvent in forming the neutral layer (18). Thus, the total process is complicated. Since the hardened patterns (16a) are not easily removed, defects might be generated when forming gabs.

### SUMMARY OF THE INVENTION

Therefore, it is an object of the present invention to a method for forming fine patterns of semiconductor device by using the DSA lithography wherein total process is simple and the guide patterns can be easily removed because guide patterns are developed with negative-tone developing solution which does not require the hardening of the guide patterns,

In order to achieve these objects, the present invention provides a method for forming fine patterns of semiconductor device, comprising the steps of: (a) forming a photoresist layer over a wafer on which an organic anti-reflection coating layer is formed; (b) exposing and developing the photoresist layer with a negative-tone developing solution to form guide patterns; (c) forming a neutral layer over the wafer on which the guide patterns are formed; (d) developing the guide patterns to remove the guide patterns and form neutral layer patterns having an opening part which was made by the removal of the guide patterns; (e) coating BCP of DSA material on the substrate on which neutral layer patterns are formed, heating the substrate at a temperature over a glass transition temperature (Tg) to form directed self-assembly patterns; and (f) selectively etching a part having relatively small etching resistivity (or high etching rate) among the directed self-assembly patterns by using O₂ plasma to form fine patterns.

In the present method for forming the fine patterns, the semiconductor patterns having 20 nm-level line width can be efficiently formed through the DSA lithography which uses guide patterns developed with the negative-tone developing solution. That is, there is not required the hardening process which is required when the photoresist patterns developed with conventional positive-tone developing solution are used as the guide patterns. Therefore, the product efficiency or yield of semiconductor device is increased and the guide patterns can be easily removed in a lift-off process, so the semiconductor patterns having 20 nm-level line width can be efficiently formed.

### BRIEF DESCRIPTION OF THE DRAWINGS

FIG. 1 is a drawing of cross-sectional views for showing a method for forming fine patterns of semiconductor device using conventional directed self assembly lithography.

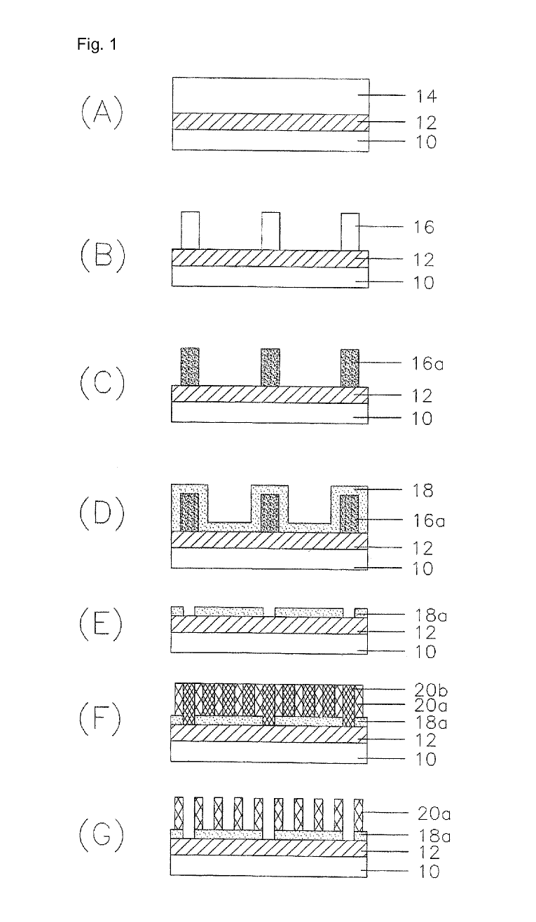

FIG. 2 is a drawing of cross-sectional views for showing a method for forming fine patterns of semiconductor device using directed self assembly lithography according to one embodiment of the present invention.

### DETAILED DESCRIPTION OF THE INVENTION

A more complete appreciation of the invention, and many of the attendant advantages thereof, will be better appreciated by reference to the following detailed description.

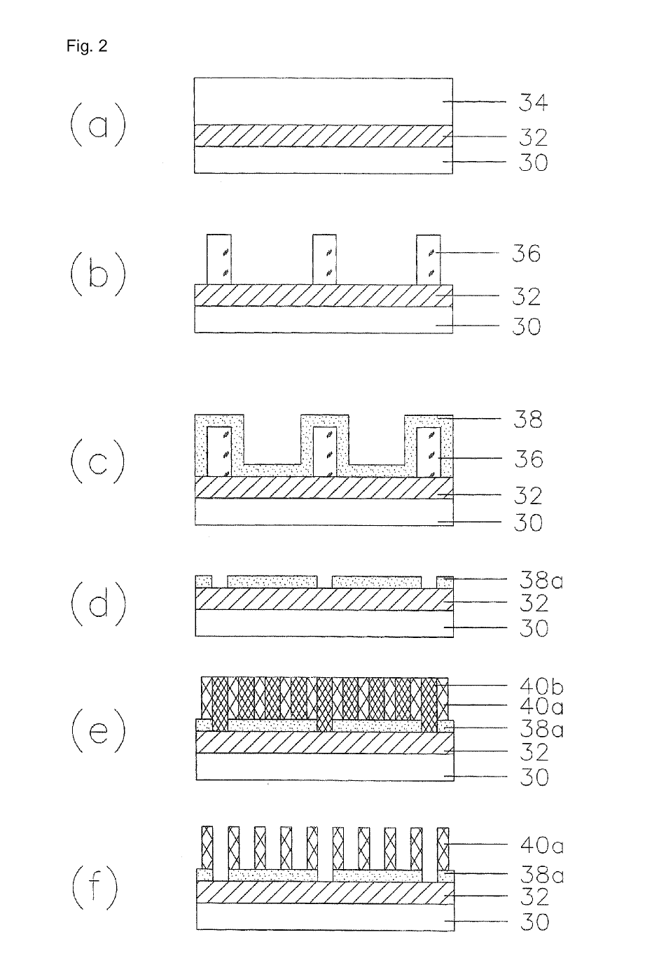

FIG. 2 is a drawing of cross-sectional views for showing a method for forming fine patterns of semiconductor device using directed self assembly lithography according to one embodiment of the present invention. As shown in FIG. 2, a method for forming fine patterns of the semiconductor device according to the present invention comprises the steps of: (a) forming a photoresist layer (34) over a substrate (30) on which an organic anti-reflection coating layer (32) is formed, (b) exposing the photoresist layer (34) and developing the same with a negative-tone developing solution to form guide patterns (36), (c) form a neutral layer (38) over the substrate on which the guide patterns (36) are formed, (d) removing the guide patterns (36) by using the developing solution, to form neutral layer patterns (38a) having an opening part which was made by the removal of the guide patterns (36); (e) coating BCP of DSA material on the substrate on which the neutral layer patterns (38a) are formed, heating the substrate at a temperature over a glass transition temperature (Tg) to form directed self-assembly patterns (40a, 40b); and (f) selectively etching a part (40b) having relatively small etching resistivity (or high etching rate) among the directed self-assembly patterns (40a, 40b) by using O₂ plasma to form fine patterns (40a).

The (a) step may be carried out the same as the conventional lithography. At needs, in the substrate (30), an underlayer such as a hard mask can be formed under the organic anti-reflection coating layer (32). The photoresist layer (34) can be formed by using a conventional photoresist composition, preferably ArF photoresist composition containing silicon component.

The guide patterns (negative-tone photoresist pattern, 36) are formed by developing the photoresist layer with a conventional negative-tone developing solution such as n-butyl acetate, n-hexanol, 4-methyl-2pentanol, and mixture thereof, after exposing the photoresist layer (34) with a given photo mask and a conventional stepper, preferably a stepper using ArF exposing light source. The unexposed part of the photoresist layer (34) is removed by the negative-tone developing solution and the exposed part (36) of the photoresist layer (34) is not removed to form the guide patterns (36). The guide patterns (36) are stripe-shape having a given pitch, for example the guide patterns (36) each is separated from the other by twice to eight times the line width of the guide pattern. The guide patterns (36) may have a minimum line width which can be defined in the exposing process, and further the line width of the guide pattern (36) can be reduced to less than the minimum line width by using a trimming process. For example, the guide patterns (36) are formed to have 50 nm line width, and then reduced to 30 nm line width through the trimming process.

The neutral layer (38) can be formed by coating (spin-coating) the conventional composition for forming the neutral layer over the substrate (30) on which the guide patterns (36) are formed and then by heating the coated neutral layer (30) at 100 to 280° C. in a nitrogen atmosphere. The conventional composition for forming the neutral layer contains random copolymer, PS-co-PMMA of styrene and methylmethacrylate (MMA), and an organic solvent such as toluene, xylene, propyleneglycol monomethylether acetate (PGMEA), propyleneglycol monomethyl ether (PGME), cyclohexanone, ethyl lactate, and mixture thereof. After heating, some of the composition for forming the neutral layer which do not react with the wafer surface (the organic anti-reflection coating layer (32), the guide patterns (36) etc.), that is unreacted random copolymer, are moved by using the organic solvent. The thickness of the neutral layer (38) is several to dozens nm, preferably 1 to 10 nm. Since the guide patterns (36) are the exposed part of the photoresist layer (34) and is not melted, bulk-exposing and hardening of the guide patterns could be omitted unlike the guide patterns (photoresist pattern) formed by a earlier positive-tone developing solution. The neutral layer (38) determines an orientation direction of stripe (lamellar) structure of BCP in the DSA lithography. When BCP is coated and heated without using the neutral layer (38), the stripe (lamellar) structure of BCP is arranged parallel to the substrate (30), thus the pattern cannot be formed at the subsequent process. While, when the neutral layer (38) is employed, the stripe (lamellar) structure of BCP is arranged perpendicular to the substrate (30), the part having low etching resistivity or a part containing oxygen component is removed at a subsequent etching process using O₂ plasma (dry etching process, (f) step), so desired semiconductor patterns can be obtained.

In the composition for forming the neutral layer, the amount of PS-co-PMMA is 0.5 to 20 weight %, preferably 0.8 to 10 weight %, more preferably 1 to 5 weight %, and the remainder is the organic solvent. When the amount of PS-co-PMMA is less than 0.5 weight %, the neutral layer cannot be formed. When the amount of PS-co-PMMA is more than 20 weight %, the viscosity of the neutral layer is excessively increased so that the neural layer becomes thicker than the target thickness. The weight-average molecular weight (Mw) of PS-co-PMMA is 5,000 to 100,000, preferably 10,000 to 20,000. When the Mw of PS-co-PMMA is less than 5,000, the quality of polymer at coating PS-co-PMMA becomes poor, and when the Mw of PS-co-PMMA is more than 100,000, the viscosity of the neutral layer is excessively increased so that the neural layer becomes thicker than the target thickness.

As the developing solution at (d) step, a conventional positive-tone developing solution such as tetramethyl ammonium hydroxide (TMAH) aqueous solution, tetrabutyl ammonium hydroxide (TBAH) aqueous solution, sodium bicarbonate aqueous solution, etc, can be used. The developing solution removes the exposed part of the photoresist layer (34), that is the guide patterns (36), to form the neutral layer patterns (38a) having an opening part which was made by the removal of the guide patterns (36). In the neutral layer patterns (38a), a part of the organic anti-reflection coating layer which is located under the guide patterns (36) being removed, is exposed. Since the organic anti-reflection coating layer (32) has a polarity, when BCP is coated and heated, one part of BCP showing polarity is in advance arranged on the exposed part of the organic anti-reflection coating layer (32) and by turns, the other part of BCP without polarity is arranged on the other part where the anti-reflection coating layer (32) is not exposed. In brief, since the neutral layer patterns (38a) is composed of composition for neutral layer (38) and each is spaced by the exposed part of the organic anti-reflection coating layer having different physical property (polarity) from the neutral layer (38), the effect of guide patterns can be obtained. As a result, the line (pattern) number of the semiconductor device per unit area can be increased and also integration degree of the semiconductor device becomes higher.

Examples of the BCP used in the present invention include a block copolymer (PS-b-PMMA) of styrene and methylmethacrylate(MMA), a block copolymer(PS-b-PSSi) of styrene and 4-(tert-butyldimehtylsilyl)oxy styrene, a block copolymer(PS-b-PDMS) of styrene and dimethylsiloxane, a block copolymer(PS-b-PVP) of styrene and vinylpyrrolidone. Generally, PS-b-PMMA is mainly used, but for high aspect ratio, PS-b-PSSi using silicon component having high etching selectivity can be used. While for improving a LER (line edge roughness), PS-b-PDMS or PS-b-PVP can be used.

When the BCP is heated at a temperature over a glass transition temperature (Tg) of the BCP, PS(or PMMA) approaches and adjoins to PS(or PMMA) according to the polarity degree difference between blocks, thereby forming a directed self assembly patterns (40a, 40b) which are arranged in a form of stripe (lamellar) perpendicularly to the substrate. The heating temperature may be varied according to the used block copolymer, for example 200 to 300° C., preferably 230 to 250° C. The heating time is 1 minute to 10 hours, preferably 1 to 60 minutes, more preferably 1 to 10 minutes. When the heating temperature is too low, the directed self assembly patterns cannot be formed, and when the heating temperature is too high, the BCP may be denaturalized. When the heating time is too short, the directed self assembly patterns cannot be formed, and when the heating time is too long, the manufacturing time becomes long and the production efficiency becomes low.

The Mw of the BCP is 3,000 to 1,000,000, preferably 30,000 to 200,000, more preferably 80,000 to 150,000. As the polydispersity (PD, weight average molecular weight/number average molecular weight) of the BCP is close to 1, the line width and line width roughness (LWR) of the patterns show good result, for example 1.0 to 1.2.

When selective etching of a part (40b) (for example, PMMA part of PS-b-PMMA) having relatively small etch resistivity (or high etch rate) among the directed self-assembled patterns (40a, 40b) is carried out by using O₂ plasma to form fine patterns (40a), fine patterns with line and space (or stripe) of 20 nm-level line width can be formed.

Hereinafter, the preferable examples are provided for better understanding of the present invention. However, the present invention is not limited by the following examples.

### EXAMPLE 1 AND COMPARATIVE EXAMPLE 1

### Formation of Fine Patterns of Semiconductor Devices and Evaluation Thereof

33 nm of ArF anti-reflection coating composition (DARC-A125, made by Dongjinsemichem Co., Ltd.) was coated on a silicon wafer and heated at 240° C. for 60 seconds. Photoresist composition (DHA-7079 (ArF photoresist), made by Dongjinsemichem Co., Ltd.) was coated and soft-baked at 105° C. for 60 seconds to form a photoresist pattern having 120 nm line width. Next, the wafer was exposed to ArF stepper having aperture number of 0.85 (ASML 1200, made by ASML) and heated at 95° C. for 60 seconds to amplify acids generated during the exposure. The heated wafer was dipped into a negative-tone developing solution (n-butyl acetate) for 60 seconds and developed to form line and space patterns (guide patterns) having 70 nm line width. In Comparative Example 1, after exposing the photoresist layer, the guide patterns were formed by using a positive-tone developing solution (TMAH aqueous solution), the guide patterns were bulk-exposed to the ArF stepper in order to prevent the guide patterns from being dissolved in the organic solvent such as toluene during the formation of the neutral layer, and the guide patterns bulk-exposed were heated at 150° C. for 60 seconds, additionally heated at 220° C. for 60 to hardened the guide patterns. On the wafer in which the guide patterns in Example 1 or the hardened guide patterns in Comparative Example 1 were formed, composition (PS-co-PMMA and toluene) for forming the neutral layer for directed self assembled lamellar structure was coated and heated at 200° C. in a nitrogen atmosphere, unreacted component of composition of the neutral layer was removed by using toluene, to form the neutral layer on the wafer surface. Next, the resultant wafer was dipped into a developing solution (TMAH aqueous solution) for 60 seconds and developed to form the guide patterns. Over the substrate (wafer) on which the neutral layer patterns are formed having an opening part which was made by the removal of the guide patterns, PS-b-PMMA dissolved in toluene was coated and heated at 240° C. for 1 hour to form directed self assembly patterns, polarity part and non polarity part being alternately disposed. The wafer on which the directed self assembly patterns were formed was cooled at room temperature, and then the PMMA of PS-b-PMMA was dry etched by using O₂ plasma etching process to form the line-and-space fine patterns having 24 nm line width. The number of defect (bridge flaw, etc.) of the fine patterns at 1 cm×1 cm was measured with an instrument for checking defect number (negavitec 3100, made by Negavitec), and the results thereof were shown in a following Table 1.

TABLE 1

| | pattern line width(nm) | flaw number (ea) |
|---|---|---|
| Example 1 | 24 | 260 |
| Comparative Example 1 | 24 | 1200 |

As described above, the method for forming fine patterns of the semiconductor device has substantially equal or superior resolution to the conventional optical method of ArF immersion method or EUVL (extreme ultraviolet lithography) method. In comparison with the method using the conventional DSA lithography in Comparative Example 1, the hardening process of the guide patterns is improved or omitted in the method for forming fine patterns of the semiconductor device according to the present invention so that the product efficiency of the semiconductor device is increased. Further the guide patterns can be effectively removed in the developing process to decrease the defect number of fine patterns.

1. A method for forming fine patterns of semiconductor devices, comprising the steps of:
(a) forming a photoresist layer over a wafer on which an organic anti-reflection coating layer is formed;
(b) exposing the photoresist layer and developing the photoresist layer with a negative-tone developing solution to form guide patterns;
(c) forming a neutral layer over the wafer on which the guide patterns are formed;
(d) developing the guide patterns to remove the guide patterns and form neutral layer patterns having an opening part which was made by the removal of the guide patterns;
(e) coating block copolymer (BCP) of directed self assembly (DSA) material on the substrate on which neutral layer patterns are formed, heating the substrate at a temperature over a glass transition temperature (Tg) to form directed self-assembly patterns; and
(f) selectively etching a part having relatively small etching resistivity (or high etching rate) among the directed self-assembly patterns by using O₂ plasma to form fine patterns.

2. The method for forming fine patterns of semiconductor devices of claim 1, wherein the neutral layer comprises a random copolymer (PS-co-PM MA) of styrene and methylmetacrylate, and an organic solvent selected from a group of toluene, xylene, propyleneglycol monomethylether acetate(PGMEA), propyleneglycol monomethyl ether(PGME), cyclohexanone, ethyl lactate and mixture thereof.

3. The method for forming fine patterns of semiconductor devices of claim 1, wherein the negative-tone developing solution is selected from a group of as n-butyl acetate, n-hexanol, 4-methyl-2pentanol and mixture thereof, and the developing solution is selected from a group of tetramethyl ammonium hydroxide (TMAH) aqueous solution, tetrabutyl ammonium hydroxide (TBAH) aqueous solution, sodium bicarbonate aqueous solution and mixture thereof.

4. The method for forming fine patterns of semiconductor devices of claim 1, wherein the BCP is selected from a group consisting of a block copolymer (PS-b-PMMA) of styrene and methylmethacrylate(MMA), a block copolymer(PS-b-PSSi) of styrene and 4-(tert-butyldimehtylsilyl)oxy styrene, a block copolymer(PS-b-PDMS) of styrene and dimethylsiloxane, a block copolymer(PS-b-PVP) of styrene and vinylpyrrolidone.

5. The method for forming fine patterns of semiconductor devices of claim 1, wherein a temperature over a glass transition temperature of the BCP is 200 to 300° C.
